(19) United States
(12) Patent Application Publication
(10) Pub. No.: US 2026/0184990 A1
(43) Pub. Date: Jul. 2, 2026

(54) SILICON ETCHANT COMPOSITION AND METHOD OF FORMING PATTERN USING THE SAME

(71) Applicant: DONGWOO FINE-CHEM CO., LTD., Jeollabuk-do (KR)

(72) Inventors: JI WON KIM, Jeollabuk-do (KR); JIN KYU ROH, Jeollabuk-do (KR); SANG KWON KIM, Jeollabuk-do (KR); HYO JOONG YOON, Jeollabuk-do (KR)

(21) Appl. No.: 19/434,633

(22) Filed: Dec. 29, 2025

(30) Foreign Application Priority Data
Dec. 30, 2024 (KR) 10-2024-0200483

(51) Int. Cl. C09K 13/00

(52) U.S. Cl. CPC C09K 13/00

(57) ABSTRACT

A silicon etchant composition includes an amine-based compound, a pyrazine compound, an alkaline compound including at least one of an organic hydroxide and an inorganic hydroxide, and a solvent. In a method of forming a pattern, a silicon-containing layer is formed on a substrate. A silicon protective layer is formed on a portion of the silicon-containing layer. The silicon-containing layer includes silicon and germanium. The silicon-containing is etched using the silicon etchant composition.

### CROSS-REFERENCE TO RELATED APPLICATION AND CLAIM OF PRIORITY

This application claims the benefit under 35 USC § 119 of Korean Patent Application No. 10-2024-0200483 filed on Dec. 30, 2024, in the Korean Intellectual Property Office, the entire disclosure of which is incorporated herein by reference for all purposes.

### BACKGROUND

### 1. Field

The present invention relates to a silicon etchant composition and a method of forming a pattern using the same.

### 2. Description of the Related Art

In a thin film transistor of a display device such as a liquid crystal display (LCD) and an organic light-emitting diode (OLED), and a semiconductor device such as a memory device, a silicon-containing substrate or a silicon layer is prepared from a silicon wafer, polysilicon, amorphous silicon, etc.

To implement a high-reliability semiconductor device process, a high etching rate and a selective etching of a target material may be required. For example, a selective etching process may be performed with respect to a silicon layer. For example, a protective layer may be formed on the silicon layer, and only the silicon layer may be selectively etched while sufficiently protecting a portion on which the protective layer is formed.

For example, additional components may be included in the etchant composition to selectively etch only the silicon layer. However, if a component such as a halide is included, an etching rate of a silicon-containing insulating layer or a silicon-containing semiconductor layer containing an element other than silicon such as a silicon oxide layer, a silicon-germanium layer, etc., may also be increased to reduce an etch selectivity for the silicon layer.

### SUMMARY

According to an aspect of the present invention, there is provided a silicon etchant composition providing enhanced etch selectivity.

According to an aspect of the present invention, there is provided a method of forming a pattern using the silicon etchant composition.
(1) A silicon etchant composition, including: an amine-based compound; a pyrazine compound; an alkaline compound including at least one of an organic hydroxide and an inorganic hydroxide; and a solvent.
(2) The silicon etchant composition of the above (1), wherein the pyrazine compound includes a carbonyl group.
(3) The silicon etchant composition of the above (1), wherein the pyrazine compound includes a compound represented by Chemical Formula 1.

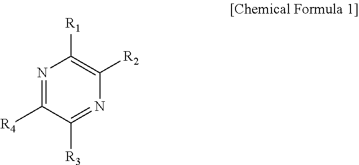

In Chemical Formula 1, R₁, R₂, R₃ and R₄ are each independently selected from the group consisting of hydrogen, halogen, a substituted or unsubstituted C1 to C5 alkyl group, a substituted or unsubstituted C2 to C5 alkenyl group, a substituted or unsubstituted C1 to C5 alkylcarbonyl group, a substituted or unsubstituted amide group, a C1 to C5 alkoxy group, an amine group, a hydroxy group, and a carboxyl group.
(4) The silicon etchant composition of the above (3), wherein in Chemical Formula 1, at least one of R₁ to R₄ is hydrogen.
(5) The silicon etchant composition of the above (3), wherein, in Chemical Formula 1, at least one of R₁ to R₄ is selected from the group consisting of a halogen, a C1 to C3 alkyl group, a C1 to C3 alkoxy group, an amide group substituted with an amine group, an amide group, an amine group, a hydroxy group, and a carboxyl group.
(6) The silicon etchant composition of the above (3), wherein at least one of R₁ to R₄ is selected from the group consisting of an amide group, an amide group substituted with an amine group, and a carboxyl group.
(7) The silicon etchant composition of the above (3), wherein the halogen is selected from the group consisting of Cl, Br and I.
(8) The silicon etchant composition of the above (1), wherein a content of the amine-based compound is in a range from 0.01 wt % to 40 wt % based on a total weight of the silicon etchant composition.
(9) The silicon etchant composition of the above (1), wherein a content of the pyrazine compound is in a range from 0.01 wt % to 20 wt % based on a total weight of the silicon etchant composition.
(10) The silicon etchant composition of the above (1), wherein a content of the alkaline compound is in a range from 0.01 wt % to 40 wt % based on the total weight of the silicon etchant composition.
(11) The silicon etchant composition of the above (1), wherein the number of amine groups in a molecule of the amine-based compound is 3 or more.
(12) The silicon etchant composition of the above (1), which a fluorine-containing compound is not included.
(13) A method of forming a pattern, including: forming a silicon-containing layer on a substrate; forming a silicon protective layer on a portion of the silicon-containing layer, the silicon-containing layer including silicon and germanium; and etching the silicon-containing layer using the above-described silicon etchant composition.
(14) The method of the above (13), wherein the silicon protective layer is used as an etching mask.
(15) The method of the above (13), wherein etching the silicon-containing layer includes etching the silicon-containing layer to form a gate pattern.

A silicon etchant composition according to embodiments of the present invention may be used to enhance an etch selectivity for a silicon layer. The silicon etchant composition may include a pyrazine-based compound, and provide improved etching rate and etch selectivity for the silicon layer.

In example embodiments, the pyrazine-based compound including a carbonyl group may be used to enhance silicon layer etching properties while suppressing an etching of a silicon-germanium layer. Thus, high etch selectivity for the silicon layer may be achieved.

### BRIEF DESCRIPTION OF THE DRAWINGS

FIGS. 1 to 7 are schematic cross-sectional views illustrating a method of forming a pattern in accordance with example embodiments.

### DETAILED DESCRIPTION OF THE EMBODIMENTS

Embodiments of the present disclosure provide a silicon etchant composition (hereinafter, abbreviated as “etchant composition”) including a pyrazine-based compound. Additionally, a method for forming a pattern using the silicon etchant composition is provided.

Hereinafter, embodiments of the present invention will be described in detail. However, these embodiments are merely provided as examples, and the present disclosure is not limited to the specific embodiments described herein.

The term “Ca to Cb Y group” used in the present specification refers to a Y group having the number of carbons of a to b. For example, Ca to Cb refers to the number of carbons of the Y group in an unsubstituted state, and an additional substituent may be bonded to the Y group.

In example embodiments, a silicon etchant composition may include an amine-based compound, a pyrazine-based compound, an alkaline compound, and a solvent.

The amine-based compound may etch a silicon layer. Additionally, a pH of the etchant composition may be adjusted or maintained to promote an etching of silicon. The term “silicon layer” used herein may refer to a wafer, a substrate, a thin film (e.g., a silicon layer formed by a deposition process), etc., that may substantially consist of silicon, and the like.

For example, the amine-based compound may include or may not include a hydroxyl group. For example, when the amine-based compound includes the hydroxyl group, a concentration of hydroxide ions in the etchant composition increases, and an etching rate may be improved. For example, when a hydroxyl group is not included, silicon of the silicon layer may react with the amine-based compound to be etched.

For example, the amine-based compound including the hydroxyl group may include 1-amino-2-propanol, 2-amino-1-butanol, 3-amino-1-propanol, 3-amino-1,2-propanediol, methyldiethanolamine, propanolamine, ethanolamine, diethanolamine, N-methylethanolamine, N-methyldiethanolamine, 2-amino-3-methyl-1-butanol, 3-amino-2,2-dimethyl-1-propanol, tris(hydroxymethyl)aminomethane, 2-amino-2-methyl-1,3-propanediol, 3-methylamino-1-propanol, 2-dimethylamino-2-methyl-1-propanol, 1-dimethylamino-2-propanol, 3-dimethylamino-1-propanol, 2-dimethylamino-1-propanol, 2-diethylamino-1-propanol, 2-diethylamino-1-ethanol, 2-ethylamino-1-ethanol, 1-(dimethylamino) 2-propanol, N-propyldiethanolamine, N-isopropyldiethanolamine, N-(2-methylpropyl) diethanolamine, N-n-butyldiethanolamine, N-t-butylethanolamine, N-cyclohexyldiethanolamine, 2-(dimethylamino) ethanol, 2-diethylaminoethanol, 2-dipropylaminoethanol, 2-butylaminoethanol, 2-t-butylaminoethanol, 2-cycloaminoethanol, 2-amino-2-pentanol, 2-[bis(2-hydroxyethyl)amino]-2-methyl-1-propanol, 2-[bis(2-hydroxyethyl)amino]-2-propanol, N,N-bis(2-hydroxypropyl) ethanolamine, 2-amino-2-methyl-1-propanol, triisopropanolamine, or the like. These may be used alone or in a combination of two or more therefrom.

For example, the amine-based compound devoid of the hydroxyl group may include 1,2-diaminopropane, diethylenetriamine, isopropylamine, triethylamine, trimethylamine, methylamine, ethylamine, aniline (aminobenzene), 2-aminopentane, diethylamine, N-dodecyldiethylamine, or the like. These may be used alone or in a combination of two or more therefrom.

For example, the amine-based compound may include a linear amine-based compound or a cyclic amine-based compound.

For example, the linear amine-based compound may include the above-mentioned compounds.

For example, the cyclic amine-based compound may include a monoazabicyclo-based compound such as 8-azabicyclo [3.2.1]octane, 11-azabicyclo [4.4.1]undecane-1,3,5,7,9-pentene, etc.; a diazabicyclo-based compound such as 1,8-diazabicyclo [6.3.2]tridecane, 1,8-diazabicyclo [5.4.0]undec-7-ene, 1,5-diazabicyclo [4.3.0]non-5-ene, 2,8-diazabicyclo [4.3.0]nonane, 1,4-diazabicyclo [4.3.0]nonane, 1,4-diazabicyclo [3.2.2]nonane, 1,4-diazabicyclo [2.2.2]octane, 1,4-diazabicyclo [3.2.1]octane, and 3-benzyl-3,8-diazabicyclo [3.2.1]octane; a triazabicyclo-based compound such as 1,5,7-triazabicyclo [4.4.0]dec-5-ene, 7-methyl-1,5,7-triazabicyclo [4.4.0]dec-5-ene, or the like. These may be used alone or in a combination of two or more therefrom.

In example embodiments, the amine-based compound may include an alkyl amine.

The alkyl amine may represent a compound including at least one of an alkyl group and an alkylene group, and an amine group. The amine group may include at least one of a primary amine group, a secondary amine group and a tertiary amine group. The secondary amine group and/or the tertiary amine group may be bonded to one or more of the alkyl group and/or the alkylene group.

For example, the alkyl amine may be represented by CₓN_{y}H_{z} (where x, y, and z are integers of 1 or more). z may be determined considering the number of carbon (x) and the number of nitrogen (y) of the alkyl amine.

For example, the alkyl amine may include 1,2-diaminopropane, isopropylamine, methylamine, ethylamine, trimethylamine, 2-aminopentane, diethylamine, triethylamine, ethylenediamine, diethylenetriamine, triethylenetetramine, tetraethylenepentaamine, pentaethylenehexaamine, 1,3-propylenediamine, dipropylenetriamine, 1,4-butadiamine, pentamethylenehexaamine, trimethylenediamine, N,N-dimethylethylenediamine, or the like. These may be used alone or in a combination of two or more therefrom.

In example embodiments, the number of amine groups in a molecule of the alkyl amine may be 3 or more. For example, the number of nitrogen atoms in the alkyl amine may be 3 or more. Accordingly, contact efficiency between the alkyl amine and silicon may be improved, and the silicon etching properties of the etchant composition may be improved.

In example embodiments, a content of the amine-based compound based on a total weight of the etchant composition may be in a range from 0.01 wt % to 40 wt %, from 0.03 wt % to 37 wt %, from 0.05 wt % to 35 wt %, from 0.08 wt % to 32 wt %, from 0.1 wt % to 30 wt %, from 0.3 wt % to 28 wt %, from 0.5 wt % to 26 wt %, from 0.7 wt % to 25 wt %, from 0.8 wt % to 23 wt %, from 0.9 wt % to 22 wt %, from 0.95 wt % to 21 wt %, or from 1 wt % to 20 wt %.

In an embodiment, the content of the amine-based compound based on the total weight of the etchant composition may be 1 wt % or more, and less than 30 wt %, in a range from 1 wt % to 20 wt %, from 1 wt % to 15 wt %, or from 1 wt % to 10 wt %.

In the above range, over-etching of the silicon-germanium layer by the etchant composition may be suppressed, and the silicon etching rate may be improved. For example, if the content is less than the above content range, an etching selectivity may be reduced due to over-etching of the silicon-germanium layer. For example, if the content exceeds the above content range, the amine-based compound may remain on a silicon surface, thereby reducing the silicon etching rate, and etching performance may be degraded.

The pyrazine-based compound may form a protective film on the silicon-germanium layer to provide an anti-corrosion (e.g., an etching suppression) of the silicon-germanium layer. For example, the pyrazine-based compound may remain on a surface of the silicon-germanium layer by a hydrogen bonding to reduce the etching rate of the surface of the silicon-germanium layer.

The pyrazine-based compound may refer to a compound including a pyrazine structure (an aromatic heterocyclic compound represented by C₄H₄N₂). For example, at least one hydrogen bonded to carbon in the pyrazine structure may be substituted.

For example, the pyrazine compound may include pyrazine, pyrazinamide, methylpyrazine, 2,3-dimethylpyrazine, 2,5-dimethylpyrazine, trimethylpyrazine, tetramethylpyrazine, ethylpyrazine, propylpyrazine, isopropylpyrazine, sec-butylpyrazine, methoxypyrazine, ethoxypyrazine, chloropyrazine, bromopyrazine, 2-methoxypyrazine-3-(1-methylpropyl) pyrazine, 3-isobutyl-2-methoxypyrazine, 2-ethoxy-3-methylpyrazine, 2-ethoxy-6-methylpyrazine, 3-hydroxypyrazine-2-carboxamide, pyrazine-2-carbohydrazide, pyrazinecarboxylic acid, 5-methylpyrazine-2-carboxylic acid, 3-aminopyrazine-2-carboxylic acid, 5-methoxypyrazine-2-carboxylic acid, 6-chloropyrazine-2-carboxylic acid, 2,3-pyrazinedicarboxylic acid, pyrazine-2,5-dicarboxylic acid, 2,6-bis(1,1-dimethylethoxy) pyrazine, 2-2-(aziridin-1-yl) ethoxy) pyrazine, or the like. These compounds may be used alone or in a combination of two or more therefrom.

In example embodiments, the pyrazine-based compound may include a carbonyl group. Accordingly, the etching rate of the silicon-germanium layer may be further reduced, thereby further improving the silicon etching selectivity.

For example, the carbonyl group may be represented by —C(═O) R. For example, R may include hydrogen, an amine group, a hydroxyl group, an alkyl group, an alkylene group, or the like.

In example embodiments, the pyrazine-based compound may include a compound represented by Chemical Formula 1.

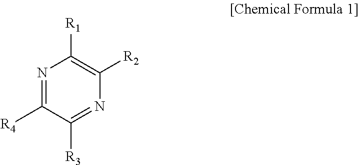

In Chemical Formula 1, R₁, R₂, R₃ and R₄ may each independently be selected from the group consisting of hydrogen, halogen, a substituted or unsubstituted C1 to C5 alkyl group, a substituted or unsubstituted C2 to C5 alkenyl group, a C1 to C5 alkylcarbonyl group, a substituted or unsubstituted amide group, a C1 to C5 alkoxy group, an amine group, a hydroxyl group, and a carboxyl group.

The alkyl group and the alkenyl group may have a linear structure or a branched structure. For example, a C3 alkyl group may include an n-propyl group, an isopropyl group, or the like.

For example, the alkylcarbonyl group in Chemical Formula 1 may be represented by —C(═O) R₅.

For example, the alkoxy group in Chemical Formula 1 may be represented by —OR₆.

For example, the amide group in Chemical Formula 1 may be represented by —C(═O)NRₐR_{b}.

For example, R₅ may be a C2 to C4 alkyl group. R₆ may be a C1 to C5 alkyl group. Rₐ and R_{b} may each independently be hydrogen or a C1 to C5 alkyl group.

The term “substituted” as used herein may indicate that any hydrogen in a hydrocarbon group is substituted with at least one selected from the group consisting of a halogen atom, a C1 to C6 alkyl group, a C2 to C6 alkenyl group, a C2 to C6 alkynyl group, a C1 to C6 alkoxy group, a C1 to C6 acetyl group, a C6 to C12 phenoxy group, a C6 to C12 aryl group, a C1 to C6 alkylsulfonyl group, a sulfonic acid group, a hydroxyl group, a nitro group, an amine group, an amide group, an alkylamine group of —NR_{c}R_{d}Rₑ (Rc, Rd and Re are each independently hydrogen or a C1 to C6 alkyl group), and a cyano group.

In example embodiments, at least one of R₁ to R₄ in Chemical Formula 1 may be hydrogen. For example, two or more of R₁ to R₄ in Chemical Formula 1 may be hydrogen.

In example embodiments, at least one of R₁ to R₄ in Chemical Formula 1 may be selected from the group consisting of a halogen, a C1 to C3 alkyl group, a C1 to C3 alkoxy group, an amide group, an amine group-substituted amide group, an amine group, a hydroxyl group, and a carboxyl group.

In some embodiments, the amine group-substituted amide group may be represented by —C(═O) NH—NH₂.

In some embodiments, two or more of R₁ to R₄ in Chemical Formula 1 may be selected from the group consisting of the amine group-substituted amide group, the amine group, the hydroxyl group and the carboxyl group.

In some embodiments, at least one of R₁ to R₄ in Chemical Formula 1 may be selected from the group consisting of the hydroxyl group, the carboxyl group and the amide group.

In example embodiments, the compound represented by Chemical Formula 1 may include a compound represented by Chemical Formula 1-1 below.

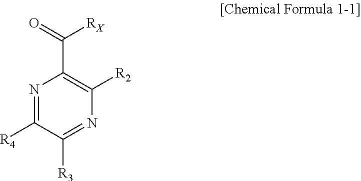

In Chemical Formula 1-1, R₂, R₃ and R₄ may each independently be selected from the group consisting of hydrogen, a halogen, a substituted or unsubstituted C1 to C5 alkyl group, a substituted or unsubstituted C2 to C5 alkenyl group, a substituted or unsubstituted C1 to C5 alkylcarbonyl group, a substituted or unsubstituted amide group, a C1 to C5 alkoxy group, an amine group, a hydroxyl group and a carboxyl group.

In Chemical Formula 1-1, Rx may be selected from the group consisting of hydrogen, an amine group, a hydroxyl group and a C1 to C3 alkyl group.

In example embodiments, Rx in Chemical Formula 1-1 may be hydrogen, an amine group or a hydroxyl group.

In example embodiments, at least one of R₂ to R₄ in Chemical Formula 1-1 may be selected from the group consisting of hydrogen, a halogen, a C1 to C3 alkyl group, a C1 to C3 alkoxy group, an amide group, an amine group-substituted amide group, an amine group, a hydroxyl group and a carboxyl group.

In example embodiments, at least one of R₂ to R₄ in Chemical Formula 1-1 may be selected from the group consisting of hydrogen, a halogen, a C1 to C3 alkyl group, a C1 to C3 alkoxy group, an amide group and a carboxyl group.

In example embodiments, halogen included in the compound represented by Chemical Formula 1 and Chemical Formula 1-1 may be selected from the group consisting of Cl, Br and I. For example, the compound represented by Chemical Formula 1 and Chemical Formula 1-1 may not include a fluorine atom. The fluorine atom included in the compound may increase an etching rate of the silicon-germanium layer to reduce the etching selectivity.

In example embodiments, the pyrazine-based compound may include at least one of pyrazinamide, 3-hydroxypyrazine-2-carboxamide, pyrazine-2-carbohydrazide, pyrazinecarboxylic acid, 5-methylpyrazine-2-carboxylic acid, 3-aminopyrazine-2-carboxylic acid, 5-methoxypyrazine-2-carboxylic acid, 6-chloropyrazine-2-carboxylic acid, 2,3-pyrazinedicarboxylic acid, and pyrazine-2,5-dicarboxylic acid.

In example embodiments, a content of the pyrazine-based compound may be in a range from 0.01 wt % to 20 wt %, from 0.03 wt % to 18 wt %, from 0.05 wt % to 17 wt %, from 0.1 wt % to 15 wt %, from 0.3 wt % to 12 wt %, from 0.5 wt % to 10 wt %, from 0.7 wt % to 8 wt %, from 0.9 wt % to 6 wt %, from 1 wt % to 4 wt %, or from 1 wt % to 3 wt % based on the total weight of the etchant composition.

In an embodiment, the content of the pyrazine-based compound may be in a range from 1 wt % to 10 wt %, 1 wt % or more and less than 10 wt %, from 1 wt % to 5 wt %, or from 1 wt % to 3 wt % based on the total weight of the etchant composition.

In the above content range, surface anti-corrosion by the etchant composition for the silicon-germanium layer may be further improved. For example, when the content of the pyrazine-based compound is excessively reduced, the anti-corrosion effect for the silicon-germanium layer may not be substantially provided, and the etching selectivity of silicon may be reduced. For example, when the content of the pyrazine-based compound is excessively increased, silicon solubility of the etchant composition may be reduced by the pyrazine-based compound to lower the etching performance.

The alkaline compound may function as a main etching agent that removes an etching target layer (for example, the silicon layer) during an etching process. For example, the alkaline compound may dissociate in a solution to generate hydroxyl ions, thereby increasing a pH of the etchant composition and dissolving silicon of the silicon layer.

In example embodiments, the alkaline compound may include at least one of an organic hydroxide and an inorganic hydroxide.

For example, the alkaline compound may include an inorganic cation or an organic cation as a cation, and a hydroxide ion as an anion.

For example, the organic hydroxide may include a quaternary alkyl ammonium hydroxide including ammonium hydroxide, tetramethylammonium hydroxide, tetraethylammonium hydroxide, tetrapropylammonium hydroxide, tetrabutylammonium hydroxide, tetrahexylammonium hydroxide, tetraoctylammonium hydroxide, benzyltriethylammonium hydroxide, diethyldimethylammonium hydroxide, methyltributylammonium hydroxide, or the like; and a compound including one of an azabicyclo-type structure, a diazabicyclo-type structure and a triazabicyclo-type structure in which nitrogen is included in a carbon bicyclo structure, and one of butane, pentane, hexane, heptane, octane, nonane, decane, undecane, dodecane, tridecane, tetradecane, nonene, decene, and undecene according to the number of carbons and the number of bonds; etc.

For example, the inorganic hydroxide may include lithium hydroxide, sodium hydroxide, potassium hydroxide, rubidium hydroxide, cesium hydroxide, francium hydroxide, or the like.

In example embodiments, the organic hydroxide may include a quaternary alkyl ammonium hydroxide.

In example embodiments, the quaternary alkyl ammonium hydroxide may include a compound represented by Chemical Formula 2.

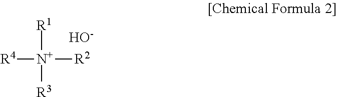

In Chemical Formula 2, R₁, R₂, R₃ and R₄ may each independently be a C1 to C8 alkyl group or an aryl group.

In example embodiments, at least one of R₁ to R₄ in Chemical Formula 2 may be a C1 to C4 alkyl group.

In example embodiments, R₁ to R₄ in Chemical Formula 2 may each independently be a C1 to C4 alkyl group.

When the number of carbon atoms of each of R₁, R₂, R₃ and R₄ is within the above range, hydroxide ion dissociating action of the quaternary alkyl ammonium hydroxide may be increased, and etching performance may be improved.

In example embodiments, a content of the alkaline compound may be in a range from 0.01 wt % to 40 wt %, from 0.03 wt % to 37 wt %, from 0.05 wt % to 35 wt %, from 0.08 wt % to 32 wt %, from 0.1 wt % to 30 wt %, from 0.3 wt % to 28 wt %, from 0.5 wt % to 26 wt %, from 0.7 wt % to 25 wt %, from 0.8 wt % to 23 wt %, from 0.9 wt % to 22 wt %, from 0.95 wt % to 21 wt %, or from 1 wt % to 20 wt % based on the total weight of the etchant composition.

In the above range, a dissociation degree of hydroxide ions or an amount dissociated from the composition may be obtained, and sufficient etching performance may be achieved.

The etchant composition may include a remaining or a residual amount of a solvent. The term “remaining” or “residual amount” used in the present disclosure may refer to a variable amount that changes according to an additional component or agent. For example, the term “remaining” or “residual amount” may indicate a remaining amount excluding the above-described amine compound, pyrazine compound and alkaline compound, or a remaining amount excluding the above-described amine compound, pyrazine compound, alkaline compound and another additive.

In example embodiments, the solvent may include water. For example, water may include distilled water, deionized water, or the like.

In some embodiments, deionized water may be used for a semiconductor process.

In some embodiments, a content of water based on the total weight of the etchant composition may be 50 wt % or more, 60 wt % or more, 70 wt % or more, 75 wt % or more, or 80 wt % or more. An upper limit of the water content may be variably adjusted according to the contents of the above-described amine compound, pyrazine compound, alkaline compound and the additive. For example, the water content may be less than 99 wt %, 98 wt % or less, 96 wt % or less, 95 wt % or less, 90 wt % or less, or 85 wt % or less.

The etchant composition may further include the additive within a range that may not degrade etching performance, anti-corrosion effect, or the like, of each of the above-described amine compound, pyrazine compound and alkaline compound. The additive may include, e.g., an etching accelerator, a corrosion inhibitor, a pH adjuster, or the like.

In some embodiments, the pH of the etchant composition may be adjusted in a range from about 11 to 14. In the pH range, damages to other insulating structures, a semiconductor pattern, a substrate, or the like, may be suppressed while etching the silicon layer.

In example embodiments, the etchant composition may not include a fluorine salt-containing compound. Accordingly, the corrosion prevention of the silicon-germanium layer and the etching selectivity for the silicon layer may be improved. For example, when the fluorine salt-containing compound is included, the etching rate for the silicon-germanium layer may be increased, and the anti-corrosion of the silicon-germanium layer may not be achieved.

For example, the fluorine salt-containing compound may represent a compound including a fluorine ion (F—). For example, the fluorine salt-containing compound may include tetramethylammonium fluoride, tetraethylammonium fluoride, diethyldimethylammonium fluoride, or the like.

In some embodiments, the etchant composition may not include a thickener such as a carboxymethyl cellulose-based compound. Accordingly, etching non-uniformity due to an increase in viscosity of the etchant composition may be prevented.

In example embodiments, the etching rate of the etchant composition for the silicon layer may be 3000 Å/min or more, 3500 Å/min or more, 4000 Å/min or more, 4500 Å/min or more, or 5000 Å/min or more. In the above range, selective etching effect of silicon may be effectively achieved, and efficiency of an etching process may be improved.

In example embodiments, the etching rate of the etchant composition for the silicon-germanium layer may be less than 35 Å/min, 30 Å/min or less, 25 Å/min or less, or 20 Å/min or less. A lower limit of the etching rate of the etchant composition for the silicon-germanium layer is not limited, but, e.g., may be 0.1 Å/min or more, or 0.5 Å/min or more. In the above range, a protective film of the insulating layer may be maintained during the etching process, and patterns may be efficiently formed.

A silicon etching using the etchant composition may be performed by a method generally known in the art. For example, a method using an immersion, a spray, or immersion and spray, or the like, may be used in a batch-type etching apparatus or a single-type etching apparatus. However, such conditions are not strictly applied and easy or suitable conditions by the person skilled in the art may be selected.

In some embodiments, the etchant composition may selectively etch the silicon layer while suppressing etching of a silicon oxide layer and/or a silicon nitride layer.

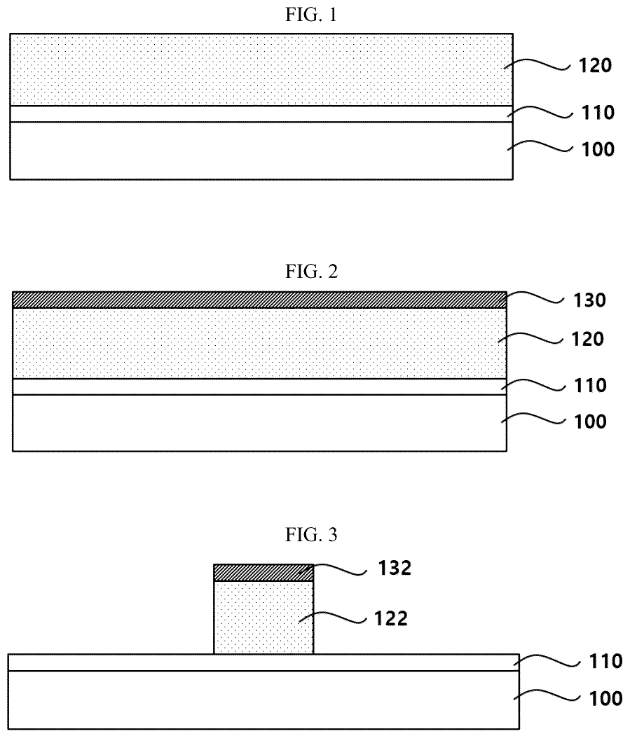

FIGS. 1 to 7 are schematic cross-sectional views illustrating a method of forming a pattern according to example embodiments.

However, the etchant composition according to embodiments is not limited as being used in the processes of FIGS. 1 to 7, and may be utilized in formation processes of various structures or patterns such as a wiring, a contact and a gates within the technical scope and spirit of the present disclosure.

For example, FIGS. 1 to 3 are schematic cross-sectional views illustrating a method of manufacturing a semiconductor device according to example embodiments.

Referring to FIG. 1, an insulating layer 110 may be formed on a substrate 100, and a silicon-containing layer 120 may be formed on the insulating layer 110.

The substrate 100 may include a semiconductor material such as single crystal silicon and single crystal germanium, or may include polysilicon.

The insulating layer 110 may be formed to include an insulating material such as silicon oxide, silicon nitride, silicon oxynitride, polysiloxane, or the like. For example, the insulating layer 110 may be formed by a chemical vapor deposition (CVD) process, a sputtering process, a physical vapor deposition (PVD) process, an atomic layer deposition (ALD) process, or the like.

The silicon-containing layer 120 may include at least one of single crystal silicon, polysilicon and amorphous silicon.

Referring to FIG. 2, a silicon protective layer 130 may be formed on the silicon-containing layer 120. The silicon protective layer 130 may be formed to include silicon and germanium. For example, the silicon protective layer 130 may be formed to include a silicon-germanium layer. For example, the silicon protective layer 130 may be formed by a CVD process, a sputtering process, a PVD process, an ALD process, or the like.

A mask pattern 132 may be formed by partially etching the silicon protective layer 130. For example, a portion of the silicon protective layer 130 may be partially etched until a portion of a top surface of the silicon-containing layer 120 is exposed.

Referring to FIG. 3, the silicon-containing layer 120 may be partially removed using the etchant composition according to the above-described example embodiments. Accordingly, a gate pattern 122 may be formed from the silicon-containing layer 120.

As described above, the etchant composition may include the pyrazine-based compound, so that etching performance for silicon and anti-corrosion for the silicon protective layer may be increased. Accordingly, the gate pattern 122 may be formed with high reliability by selectively etching only the silicon-containing layer 120 while effectively preventing etching of the mask pattern 132.

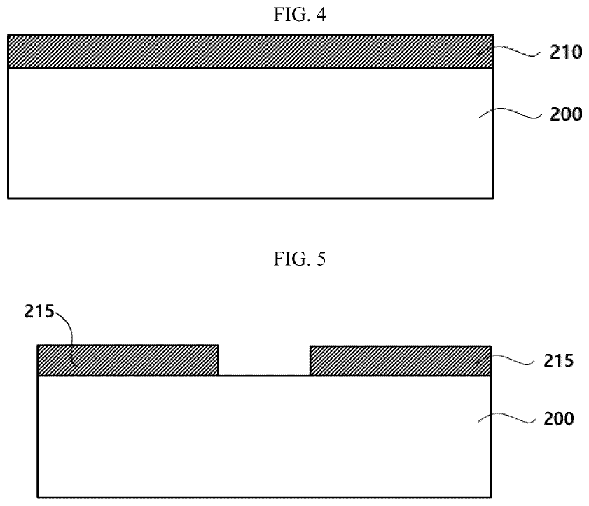

FIGS. 4 to 7 are schematic cross-sectional views illustrating a method of forming a pattern according to example embodiments. Specifically, FIGS. 4 to 7 are schematic cross-sectional views illustrating a method of a shallow trench isolation (STI) according to example embodiments.

Referring to FIG. 4, a silicon protective layer 210 may be formed on a substrate 200.

The substrate 200 may be a silicon substrate including single crystal silicon, polysilicon, or amorphous silicon.

The silicon protective layer 210 may include silicon and germanium. In this case, the silicon protective layer 210 may be formed by a chemical vapor deposition (CVD) process, a sputtering (sputtering) process, a physical vapor deposition (PVD) process, an atomic layer deposition (ALD) process, or the like, so that the silicon protective layer 210 may cover a top surface of the substrate 200.

Referring to FIG. 5, a mask pattern 215 may be formed by partially etching the silicon protective layer 210. For example, a portion of the silicon protective layer 210 may be etched until a portion of a top surface of the substrate 200 is exposed.

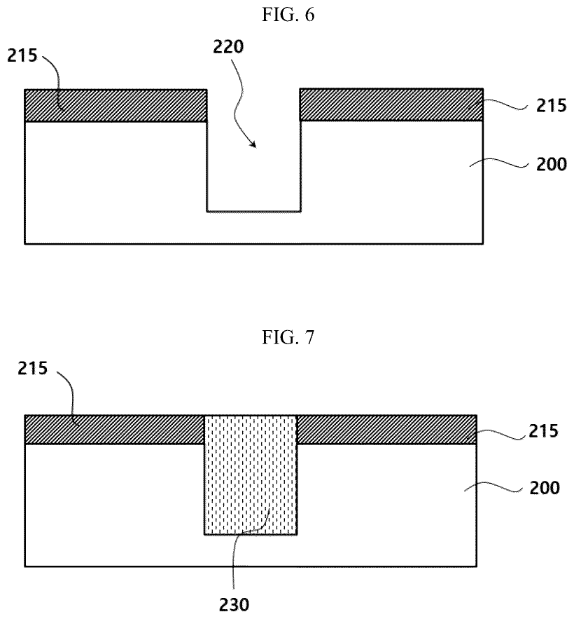

Referring to FIG. 6, an upper portion of the substrate 200 may be partially etched using the etchant composition according to the above-described example embodiments. Accordingly, a trench 220 may be formed at an inside of the substrate 200.

As described above, by using the etchant composition, etching of the mask pattern 215 may be prevented, and only the upper portion of the substrate 200 may be selectively etched. Thus, e.g., in a nano-scale fine etching process, the upper portion of the substrate 200 may be removed without etching defects, and a highly reliable etching process may be performed.

Referring to FIG. 7, an insulating pattern 230 may be formed in the trench 220.

The insulating pattern 230 may be formed to include an insulating material including silicon oxide, silicon nitride, silicon oxynitride, polysiloxane, or the like. For example, the insulating material may be formed through a CVD process, a sputtering process, a PVD process, an ALD process, or the like, to fill the trench 220.

Hereinafter, embodiments of the present disclosure will be further described with reference to specific experimental examples. Examples and comparative examples included in the experimental examples are merely provided to facilitate understanding of the present disclosure and are not intended to limit the scope of the appended claims, and it is obvious to those skilled in the art that various changes and modifications to the examples are possible within the scope and technical spirit of the present disclosure, and it is also obvious that such variations and modifications fall within the scope of the appended claims.

### Examples and Comparative Examples

Silicon etchant compositions were prepared as shown in in Tables 1 and 2 below. Water was added as a remaining amount (balance) so that a total weight of each composition became 100 parts by weight.

TABLE 1

| | amine-based | | cyclic | | alkaline | | | |
|---|---|---|---|---|---|---|---|---|
| | compound | | compound | | compound | | | |
| Category | category | content | category | content | category | content | fluoride | water |
| Example 1 | A-1 | 0.05 | B-1 | 3 | D-1 | 1 | — | Balance |
| Example 2 | A-1 | 0.1 | B-1 | 3 | D-1 | 1 | — | Balance |
| Example 3 | A-1 | 1 | B-1 | 3 | D-1 | 1 | — | Balance |
| Example 4 | A-1 | 10 | B-1 | 3 | D-1 | 1 | — | Balance |
| Example 5 | A-1 | 20 | B-1 | 3 | D-1 | 1 | — | Balance |
| Example 6 | A-1 | 30 | B-1 | 3 | D-1 | 1 | — | Balance |
| Example 7 | A-1 | 37 | B-1 | 3 | D-1 | 1 | — | Balance |
| Example 8 | A-1 | 20 | B-1 | 0.05 | D-1 | 1 | — | Balance |
| Example 9 | A-1 | 20 | B-1 | 0.1 | D-1 | 1 | — | Balance |
| Example 10 | A-1 | 20 | B-1 | 1 | D-1 | 1 | — | Balance |
| Example 11 | A-1 | 20 | B-1 | 3 | D-1 | 1 | — | Balance |
| Example 12 | A-1 | 20 | B-1 | 10 | D-1 | 1 | — | Balance |
| Example 13 | A-1 | 20 | B-1 | 17 | D-1 | 1 | — | Balance |
| Example 14 | A-1 | 20 | B-1 | 3 | D-1 | 0.05 | — | Balance |
| Example 15 | A-1 | 20 | B-1 | 3 | D-1 | 0.1 | — | Balance |
| Example 16 | A-1 | 20 | B-1 | 3 | D-1 | 1 | — | Balance |
| Example 17 | A-1 | 20 | B-1 | 3 | D-1 | 20 | — | Balance |
| Example 18 | A-1 | 20 | B-1 | 3 | D-1 | 30 | — | Balance |
| Example 19 | A-1 | 20 | B-1 | 3 | D-1 | 37 | — | Balance |
| Example 20 | A-1 | 20 | B-2 | 3 | D-1 | 1 | — | Balance |
| Example 21 | A-1 | 20 | B-3 | 3 | D-1 | 1 | — | Balance |
| Example 22 | A-1 | 20 | B-4 | 3 | D-1 | 1 | — | Balance |
| Example 23 | A-1 | 20 | B-5 | 3 | D-1 | 1 | — | Balance |
| Example 24 | A-1 | 20 | B-6 | 3 | D-1 | 1 | — | Balance |
| Example 25 | A-1 | 20 | B-7 | 3 | D-1 | 1 | — | Balance |
| Example 26 | A-1 | 20 | B-8 | 3 | D-1 | 1 | — | Balance |
| Example 27 | A-1 | 20 | B-9 | 3 | D-1 | 1 | — | Balance |
| Example 28 | A-1 | 20 | B-10 | 3 | D-1 | 1 | — | Balance |
| Example 29 | A-1 | 20 | B-11 | 3 | D-1 | 1 | — | Balance |
| Example 30 | A-2 | 20 | B-1 | 3 | D-1 | 1 | — | Balance |
| Example 31 | A-3 | 20 | B-1 | 3 | D-1 | 1 | — | Balance |
| Example 32 | A-4 | 20 | B-1 | 3 | D-1 | 1 | — | Balance |
| Example 33 | A-5 | 20 | B-1 | 3 | D-1 | 1 | — | Balance |
| Example 34 | A-1 | 20 | B-1 | 3 | D-2 | 1 | — | Balance |
| Example 35 | A-1 | 20 | B-1 | 3 | D-3 | 1 | — | Balance |
| Comparative | A-1 | 20 | — | — | — | — | — | Balance |
| Example 1 | | | | | | | | |
| Comparative | — | — | B-1 | 3 | — | — | — | Balance |
| Example 2 | | | | | | | | |
| Comparative | — | — | — | — | D-1 | 1 | — | Balance |
| Example 3 | | | | | | | | |
| Comparative | A-1 | 20 | B-1 | 3 | — | — | — | Balance |
| Example 4 | | | | | | | | |
| Comparative | A-1 | 20 | — | — | D-1 | 1 | — | Balance |
| Example 5 | | | | | | | | |
| Comparative | — | — | B-1 | 3 | D-1 | 1 | — | Balance |
| Example 6 | | | | | | | | |
| Comparative | A-1 | 20 | C-1 | 3 | D-1 | 1 | — | Balance |
| Example 7 | | | | | | | | |
| Comparative | A-1 | 20 | C-2 | 3 | D-1 | 1 | — | Balance |
| Example 8 | | | | | | | | |
| Comparative | A-1 | 20 | C-3 | 3 | D-1 | 1 | — | Balance |
| Example 9 | | | | | | | | |
| Comparative | A-1 | 20 | — | — | D-1 | 1 | F-1 | Balance |
| Example 10 | | | | | | | (0.5 | |
| | | | | | | | parts by | |
| | | | | | | | weight) | |

### Amine-Based Compound

A-1: triethylenetetramine
A-2: diethylenetriamine
A-3: tetraethylenepentamine
A-4: tripropylenetetramine
A-5: ethylenediamine

### Cyclic Compound

B-1: pyrazinamide
B-2:3-hydroxypyrazine-2-carboxamide
B-3: pyrazine-2-carbohydrazide
B-4: pyrazinecarboxylic acid
B-5:5-methylpyrazine-2-carboxylic acid
B-6:3-aminopyrazine-2-carboxylic acid
B-7:5-methoxypyrazine-2-carboxylic acid
B-8:6-chloropyrazine-2-carboxylic acid
B-9:2,3-pyrazinedicarboxylic acid
B-10: pyrazine-2,5-dicarboxylic acid
B-11: pyrazine
C-1: piperazine
C-2: pyridine
C-3: pyridine-2-carboxylic acid

### Alkaline Compound

D-1: tetramethylammonium hydroxide
D-2: ammonium hydroxide
D-3: potassium hydroxide

### Fluoride

F-1: tetramethylammonium fluoride

### Water

ultrapure water

### Experimental Example

### Experimental Example 1: Evaluation on Silicon Etching Performance

A specimen was prepared by cutting a silicon wafer to a size of 1.5 cm×1.5 cm. The specimen was immersed in each etchant composition of Examples and Comparative Examples. A temperature of the etchant composition was maintained at 70° C., and the specimen was immersed while stirring at a speed of 400 rpm for 5 minutes.

Thereafter, the specimen was taken out, washed with water, and then dried using air. An etching rate of a silicon layer was calculated from a layer thickness change value before and after immersion through an SEM analysis. An etching performance was evaluated according to the following criteria.

### <Evaluation Criteria>

⊚: etching rate of 4000 Å/min or more
∘: etching rate of 3500 Å/min or more, and less than 4000 Å/min
Δ: etching rate of 3000 Å/min or more, and less than 3500 Å/min
X: etching rate of less than 3000 Å/min

### Experimental Example 2. Evaluation on Anti-Corrosion Property of Silicon-Germanium Layer

A specimen was prepared by cutting a silicon-germanium layer to a size of 1.5 cm×1.5 cm. The specimen was immersed in each etchant composition of Examples and Comparative Examples. A temperature of the etchant composition was maintained at 70° C., and the specimen was immersed while stirring at a speed of 400 rpm for 1 minute.

Thereafter, the specimen was taken out, washed with water, and then dried using air. An etching rate of the silicon-germanium layer was calculated from a layer thickness change value of the silicon-germanium layer before and after immersion using an ellipsometer. The etching rate was evaluated according to the following criteria.

### <Evaluation Criteria>

⊚: etching rate of 25 Å/min or less
∘: etching rate of more than 25 Å/min, and 30 Å/min or less
Δ: etching rate of more than 30 Å/min, and 35 Å/min or less
X: etching rate of more than 35 Å/min

The evaluation results of Experimental Examples are shown in Table 2 below.

TABLE 2

| | category | |
|---|---|---|
| | silicon etching | anti-corrosion of |
| | performance | silicon-germanium layer |
| Example 1 | Δ | ◯ |
| Example 2 | ◯ | ◯ |
| Example 3 | ⊚ | ⊚ |
| Example 4 | ⊚ | ⊚ |
| Example 5 | ⊚ | ⊚ |
| Example 6 | ⊚ | ◯ |
| Example 7 | ⊚ | Δ |
| Example 8 | ⊚ | Δ |
| Example 9 | ⊚ | ◯ |
| Example 10 | ⊚ | ⊚ |
| Example 11 | ⊚ | ⊚ |
| Example 12 | ◯ | ⊚ |
| Example 13 | Δ | ⊚ |
| Example 14 | Δ | ⊚ |
| Example 15 | ◯ | ⊚ |
| Example 16 | ⊚ | ⊚ |
| Example 17 | ⊚ | ⊚ |
| Example 18 | ⊚ | ◯ |
| Example 19 | ⊚ | Δ |
| Example 20 | ⊚ | ⊚ |
| Example 21 | ⊚ | ⊚ |
| Example 22 | ⊚ | ⊚ |
| Example 23 | ⊚ | ◯ |
| Example 24 | ⊚ | ◯ |
| Example 25 | ⊚ | ◯ |
| Example 26 | ⊚ | ◯ |
| Example 27 | ⊚ | ◯ |
| Example 28 | ⊚ | ◯ |
| Example 29 | ◯ | Δ |
| Example 30 | ⊚ | Δ |
| Example 31 | ⊚ | ◯ |
| Example 32 | ⊚ | ◯ |
| Example 33 | ⊚ | Δ |
| Example 34 | ⊚ | ◯ |
| Example 35 | ⊚ | ◯ |
| Comparative Example 1 | ◯ | X |
| Comparative Example 2 | X | ◯ |
| Comparative Example 3 | ⊚ | X |
| Comparative Example 4 | X | ⊚ |
| Comparative Example 5 | ⊚ | X |
| Comparative Example 6 | ◯ | X |
| Comparative Example 7 | ◯ | X |
| Comparative Example 8 | ◯ | X |
| Comparative Example 9 | ◯ | X |
| Comparative Example 10 | Δ | X |

Referring to Table 2, in Examples including the amine compound, the pyrazine compound among the cyclic compounds, the alkaline compound and the solvent, the silicon etch performance and the anti-corrosion performance of the silicon-germanium layer were improved compared to those from Comparative Examples.

In Example 1 where the content of the amine compound was relatively low, the anti-corrosion performance of the silicon-germanium layer was relatively lowered.

In Example 7 where the content of the amine compound was relatively high, the anti-corrosion performance of the silicon-germanium layer was relatively lowered.

In Example 8, where the content of the pyrazine compound was relatively low, the anti-corrosion performance of the silicon-germanium layer was relatively lowered.

In Example 13 where the content of the pyrazine compound was relatively high, the silicon etch performance was relatively lowered.

In Example 14 where the content of the alkaline compound was relatively low, the silicon etch performance was relatively lowered.

In Example 19 where the content of the alkaline compound was relatively high, the anti-corrosion performance of the silicon-germanium layer was relatively lowered.

In Example 27 where the pyrazine-based compound devoid of a carbonyl group was included, the anti-corrosion performance of the silicon-germanium layer was relatively lowered.

In Examples 30 and 33 where the number of amine groups of the amine-based compound was relatively small, the anti-corrosion performance of the silicon-germanium layer was relatively lowered.

In Comparative Example 10 including the fluoride, the silicon etch performance and the anti-corrosion performance of the silicon-germanium layer were significantly degraded.

What is claimed is:

1. A silicon etchant composition comprising:
an amine-based compound;
a pyrazine compound;
an alkaline compound comprising at least one of an organic hydroxide and an inorganic hydroxide; and
a solvent.

2. The silicon etchant composition of claim 1, wherein the pyrazine compound includes a carbonyl group.

3. The silicon etchant composition of claim 1, wherein the pyrazine compound includes a compound represented by Chemical Formula 1: 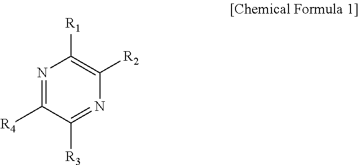
wherein, in Chemical Formula 1, R₁, R₂, R₃ and R₄ are each independently selected from the group consisting of hydrogen, halogen, a substituted or unsubstituted C1 to C5 alkyl group, a substituted or unsubstituted C2 to C5 alkenyl group, a substituted or unsubstituted C1 to C5 alkylcarbonyl group, a substituted or unsubstituted amide group, a C1 to C5 alkoxy group, an amine group, a hydroxy group, and a carboxyl group.

4. The silicon etchant composition of claim 3, wherein in Chemical Formula 1, at least one of R₁ to R₄ is hydrogen.

5. The silicon etchant composition of claim 3, wherein, in Chemical Formula 1, at least one of R₁ to R₄ is selected from the group consisting of a halogen, a C1 to C3 alkyl group, a C1 to C3 alkoxy group, an amide group substituted with an amine group, an amide group, an amine group, a hydroxy group, and a carboxyl group.

6. The silicon etchant composition of claim 3, wherein at least one of R₁ to R₄ is selected from the group consisting of an amide group, an amide group substituted with an amine group, and a carboxyl group.

7. The silicon etchant composition of claim 3, wherein the halogen is selected from the group consisting of Cl, Br and I.

8. The silicon etchant composition of claim 1, wherein a content of the amine-based compound is in a range from 0.01 wt % to 40 wt % based on a total weight of the silicon etchant composition.

9. The silicon etchant composition of claim 1, wherein a content of the pyrazine compound is in a range from 0.01 wt % to 20 wt % based on a total weight of the silicon etchant composition.

10. The silicon etchant composition of claim 1, wherein a content of the alkaline compound is in a range from 0.01 wt % to 40 wt % based on the total weight of the silicon etchant composition.

11. The silicon etchant composition of claim 1, wherein the number of amine groups in a molecule of the amine-based compound is 3 or more.

12. The silicon etchant composition of claim 1, which a fluorine-containing compound is not included.

13. A method of forming a pattern, the method comprising:
forming a silicon-containing layer on a substrate;
forming a silicon protective layer on a portion of the silicon-containing layer, the silicon-containing layer including silicon and germanium; and
etching the silicon-containing layer using the silicon etchant composition of claim 1.

14. The method of claim 13, wherein the silicon protective layer is used as an etching mask.

15. The method of claim 13, wherein etching the silicon-containing layer comprises etching the silicon-containing layer to form a gate pattern.
